(19) United States
(12) Patent Application Publication
(10) Pub. No.: US 2016/0043259 A1
(43) Pub. Date: Feb. 11, 2016

(54) Non-Imaging Light Concentrator

(71) Applicant: Sun Edge LLC, Bear (DE)

(72) Inventor: David Argentar, Bear, DE (US)

(21) Appl. No.: 14/664,209

(22) Filed: Mar. 20, 2015

Related U.S. Application Data
(63) Continuation of application No. 12/767,428, filed on Apr. 26, 2010, now abandoned.
(60) Provisional application No. 61/214,646, filed on Apr. 27, 2009.

(51) Int. Cl. H01L 31/054; G02B 19/00

(52) U.S. Cl. CPC H01L 31/0547; G02B 19/0028; G02B 19/0042; H01L 31/0543

(57) ABSTRACT

An apparatus includes a light concentrator, which during operation directs light from an entrance aperture and an exit aperture, and a photovoltaic device positioned relative to the exit aperture to receive the light. The light concentrator includes a hollow body formed from a pair of spaced-apart sidewalls and an exit wall connecting the sidewalls, each sidewall being formed from a material having a first refractive index, n₁, the exit wall includes a first element having an exit surface positioned at the exit aperture, the first element being formed from a material having second refractive index, n₂, and the hollow body contains a liquid having a having a refractive index n₃, where n₃<n₁ and n₃<n₂.

### CROSS-REFERENCE TO RELATED APPLICATIONS

This application is a continuation of U.S. application Ser. No. 12/767,428, filed on Apr. 26, 2010, which claims priority to Provisional Application No. 61/214,646, entitled “Liquid Filled Non-imaging Optical Concentrator,” filed on Apr. 27, 2009, the entire contents of which is incorporated herein by reference.

### TECHNICAL FIELD

This invention relates to a non-imaging optical concentrator and systems using the non-imaging optical concentrator.

### BACKGROUND

Solar panels can be used to convert sunlight into electricity using the photovoltaic effect. Solar panels can supply a substantial proportion of the electricity needs of a typical household. They are often mounted on the roof or on the ground and connected to the local electric utility, either supplying all the power directly to the home or pumping the excess back to the utility. In addition to reducing an homeowner's utility electricity bill, homeowners can often sell any surplus electricity directly back to the utility. Solar panels are also used for commercial applications ranging from large-scale power plants to small family-run businesses.

Non-imaging optical concentrators (also referred to as “collectors” and the terms are used interchangeably herein) can be used to improve efficiency of solar panels by concentrating sunlight onto the panel.

### SUMMARY

Light concentrators can be composed of two or more dielectric materials used to direct light to an absorber element, such as a photovoltaic cell. The use of dielectric materials allows the use of total internal reflection in places, obviating the need for metal mirrors. In embodiments, collectors feature one or more solid dielectric materials that form a thin shell around a liquid (e.g., water) dielectric layer.

In embodiments where collectors are composed of solid portions having multiple different refractive indices, different materials having discrete optical interfaces can be used, as opposed to materials that have a continuously varying refractive index (e.g., so-called Graded Index materials). In some embodiments, portions having differing refractive indices are primarily used near the concentrator exit (i.e., close to the absorber element). Portions having different refractive indices can be arranged so that the refractive index gets larger as light gets closer to the exit. It is believed that increasing the refractive index of the collector as the light gets closer to the ext allows the collector to act, in terms of its maximum theoretically permissible product of concentration ratio and light acceptance angle, as though it was entirely formed of the highest refractive index material at the exit.

In general, in one aspect, the invention features an apparatus including a light concentrator which during operation directs light from an entrance aperture and an exit aperture, and a photovoltaic device positioned relative to the exit aperture to receive the light, where the light concentrator includes a hollow body formed from a pair of spaced-apart sidewalls and an exit wall connecting the sidewalls, each sidewall being formed from a material having a first refractive index, n₁, the exit wall includes a first element having an exit surface positioned at the exit aperture, the first element being formed from a material having second refractive index, n₂, and the hollow body contains a liquid having a having a refractive index n₃, where n₃<n₁ and n₃<n₂.

Embodiments of the apparatus can include one or more of the following features. For example, the sidewalls can extend along a first direction and be arranged symmetrically with respect to a reference plane that extends along the first direction, each wall having an inner surface and an outer surface, where the inner surfaces of the walls face each other, wherein for a cross-section perpendicular to the reference plane, at least a portion of the outer surfaces have a curved shape. The curved shape can be a parabolic shape. In some embodiments, the entire outer surface has a parabolic shape. The light concentrator can include an entrance wall connecting the sidewalls opposite the exit wall, where a surface of the entrance wall corresponds to the entrance aperture, the surface corresponding to the entrance aperture being a planar surface.

The curved shape can be a hyperbolic shape. For example, the entire outer surface can have a hyperbolic shape. The light concentrator can include an entrance wall connecting the sidewalls opposite the exit wall, where a surface of the entrance wall corresponds to the entrance aperture, the surface corresponding to the entrance aperture being a convex surface.

At least a portion of the inner surfaces can have a curved shape. For example, the entire inner surface can have a parabolic or hyperbolic shape.

In some embodiments, the inner and out surfaces have the same shape. Alternatively, the inner and outer surfaces can have different shapes.

Different portions of the outer surfaces can have different shapes. In some embodiments, at least a portion of the outer surfaces have a linear shape.

The light concentrator can include an entrance wall connecting the sidewalls opposite the exit wall, where a surface of the entrance wall corresponds to the entrance aperture. The surface corresponding to the entrance aperture can be a planar surface or a convex surface.

The exit wall can include a second element positioned between the first element and the liquid, the second element being formed from a material having a refractive index n₄, where n₃<n₄<n₂. In some embodiments, the exit wall includes a third element positioned between the second element and the liquid, the third element being formed from a material having a refractive index ns, where n₃<n₅<n₄<n₂.

The first element can be formed from an inorganic glass or a polymer, such as polycarbonate.

n₂ can be 1.5 or more. The liquid can be water or an aqueous solution. In some embodiments, the liquid is glycerin.

In certain embodiments, n₃<1.41, such as 1.4 or less, 1.35 or less.

The first element can have a non-planar surface opposite the exit surface. For example, the non-planar surface can be a convex surface. In some embodiments, the non-planar surface is composed of one or more planar segments.

The inner surface of the sidewalls can be continuously curved with a surface of the first element.

The sidewalls and the first element can be formed from the same material. In some embodiments, the sidewalls and first element are formed of a single piece of the material.

In certain embodiments, n₁=n₂.

The light concentrator can be an all-dielectric collector.

The light concentrator can contain no metal components.

In general, in a further aspect, the invention features an apparatus including a light concentrator which during operation directs light from an entrance aperture and an exit aperture, and a photovoltaic device positioned relative to the exit aperture to receive the light. The light concentrator includes a hollow body formed from a pair of spaced-apart sidewalls and an exit wall connecting the sidewalls, the exit wall includes a first element having an exit surface positioned at the exit aperture and an entrance surface opposite the exit surface, the entrance surface being a non-planar surface, the first element being formed from a material having second refractive index, n₁, and the hollow body contains a liquid having a having a refractive index n₂, where n₂<n₁.

Embodiments of the apparatus can include one or more of the features mentioned above.

In general, in another aspect, the invention features an apparatus that includes a light concentrator which during operation directs light from an entrance aperture and an exit aperture and a photovoltaic device positioned relative to the exit aperture to receive the light. The light concentrator includes a hollow body formed from a pair of spaced-apart sidewalls and an exit wall connecting the sidewalls, where the sidewalls extend along a first direction, the sidewalls being arranged symmetrically with respect to a reference plane that extends along the first direction, each sidewall having an inner surface and an outer surface, where the inner surfaces of the sidewalls face each other where, for a cross-section perpendicular to the reference plane, a shape of the outer surface is different from a shape of the inner surface, the exit wall comprises a first element having an exit surface positioned at the exit aperture, the first element being formed from a material having second refractive index, n₁, and the hollow body contains a liquid having a having a refractive index n₂, where n₂<n₁.

Embodiments of the apparatus can include one or more of the features mentioned above.

In general, in a further aspect, the invention features an apparatus that includes a light concentrator which during operation directs light from an entrance aperture and an exit aperture and a photovoltaic device positioned relative to the exit aperture to receive the light. The light concentrator includes a hollow body formed from a pair of spaced-apart sidewalls and an exit wall connecting the sidewalls, where the sidewalls extend along a first direction, the sidewalls being arranged symmetrically with respect to a reference plane that extends along the first direction, each sidewall having an inner surface and an outer surface, where the inner surfaces of the sidewalls face each other where, for a cross-section perpendicular to the reference plane, a shape of the outer surface includes a curved portion and a linear portion, the exit wall includes a first element having an exit surface positioned at the exit aperture, the first element being formed from a material having second refractive index, n₁, and the hollow body contains a liquid having a having a refractive index n₂, where n₂<n₁.

Embodiments of the apparatus can include one or more of the features mentioned above.

Embodiments of the light concentrators can include one or more of the following advantages. In some embodiments, concentrators have larger acceptance angles than conventional (e.g., image forming concentrators) light concentrators. For example, including a series of refractive elements at the side of the collector closest to the absorber element can provide a larger collection angle compared to a similar collector featuring only a single refractive element, particularly where the refractive elements have monotonically increasing refractive indexes with the highest refractive index element being adjacent the absorber element.

Light collectors can use safe, inexpensive liquids (e.g., water) as their bulk media. For example, a light collector can define a hollow body that can be filled with water, where the water serves as an initial refractive medium for collected light.

Light collectors can use inexpensive materials for other components too. For example, in certain embodiments, the collectors can feature a hollow body formed from solid dielectric materials, such as transparent polymers and/or inorganic glasses. Relatively little solid material can be used. For example, the bulk of a collector can be composed of a liquid (e.g., water). The light collectors can be devoid of any metal components.

Modules using light collectors can provide year round (or nearly year round) solar power without the use of solar tracking systems. For example, light collectors can have sufficiently large collection angles that, when mounted in solar panels, they can provide electricity year round from stationary positions at sub-tropical and temperate latitudes.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1A is a perspective view of an embodiment of a solar collector system.

FIG. 1B is a cross-sectional view of the solar collector system shown in FIG. 1A.

FIG. 1C is a cross-sectional view of a portion of the solar collector system shown in FIG. 1A.

FIG. 2A is a cross-sectional view of another embodiment of a solar collector system.

FIG. 2B is a cross-sectional view of a portion of the solar collector system shown in FIG. 2A.

FIG. 3A is a cross-sectional view of another embodiment of a solar collector system.

FIG. 3B is a cross-sectional view of a portion of the solar collector system shown in FIG. 3A.

FIG. 4 is a cross-sectional view of an embodiment of a collector.

FIG. 5 is a cross-section view of a portion of a collector.

FIG. 6 is a perspective view of an embodiment of a solar panel including collectors.

FIG. 7 is a schematic view of an embodiment of a solar panel system.

Like reference symbols in the various drawings indicate like elements.

### DETAILED DESCRIPTION

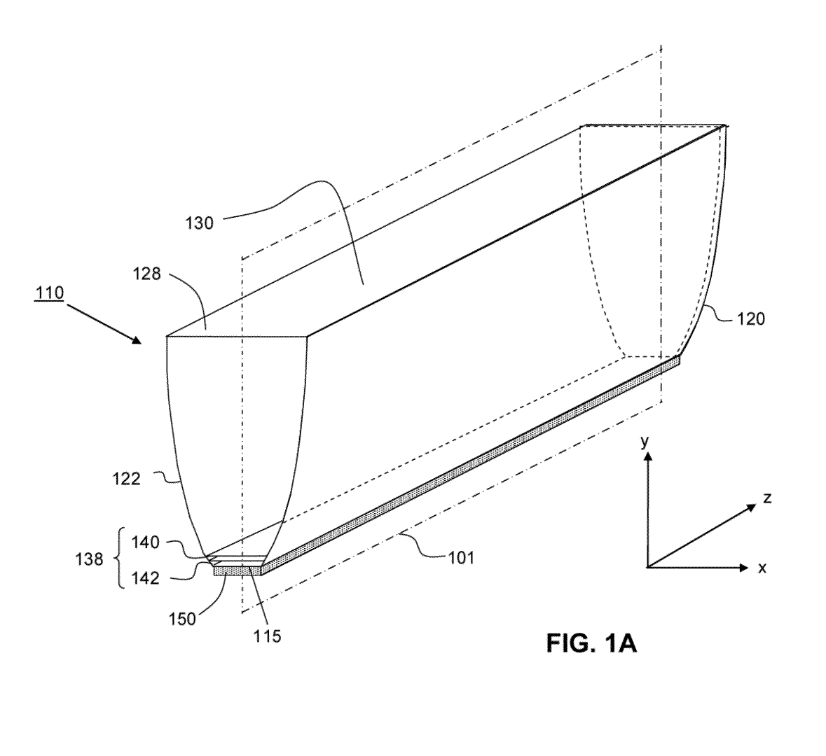

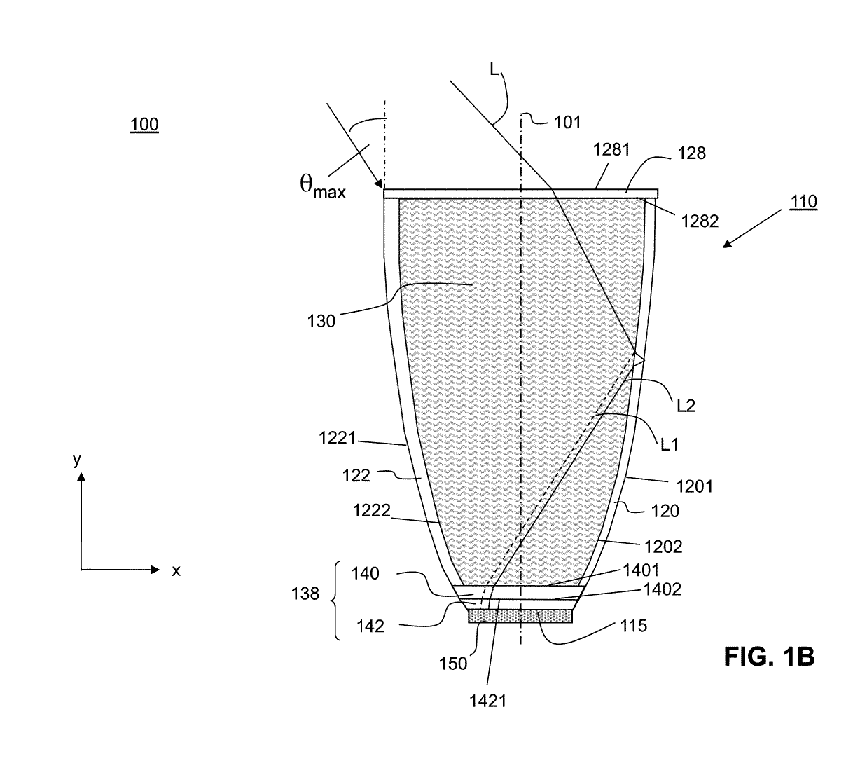

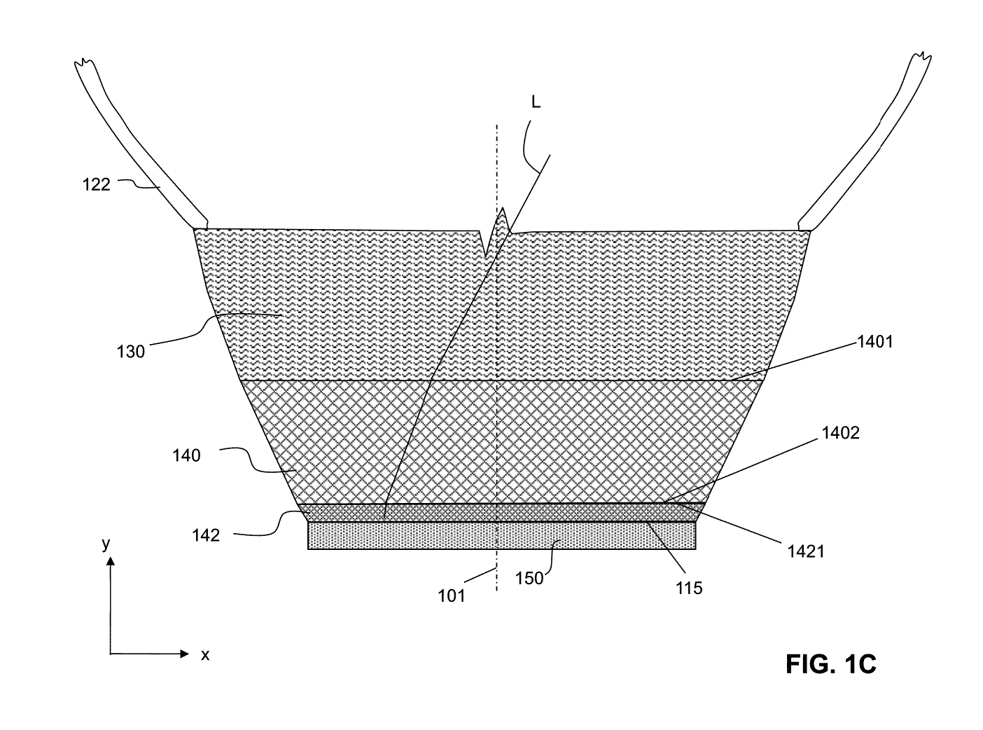

Referring to FIG. 1A, a solar collector system 100 includes a collector 110 and an absorber element 150, such as a solar cell. Collector 110 operates to concentrate incident solar radiation over a wide range of angles onto absorber element 150.

Collector 110 has a hollow body 130 composed of two curved sidewalls 120 and 122, which extend along an axis (the y-axis of the Cartesian coordinate system shown). Sidewalls 120 and 122 are symmetric with respect to a reference plane 101, parallel to the y-z plane. Collector 110 includes an exit wall 138 extending between an edge of sidewalls 120 and 122 forming a wall for hollow body 120 at one end. Exit wall 138 corresponds to an exit aperture for collector 110. In collector 110, exit wall 138 is composed of two refractive elements, labeled 140 and 142 respectively. Absorber element 150 is attached to collector 110 at an exit surface 115 of exit wall 138. Collector 110 also includes an entrance wall 128 on the opposite side of collector 110 from exit wall 138. Entrance wall 128 corresponds to an entrance aperture for collector 110.

Referring also to FIG. 1B, sidewalls 120 and 122 each have an inner surface (1202 and 1222, respectively) and an outer surface (1201 and 1221, respectively). In some embodiments, as for the embodiment shown in FIGS. 1A and 1B, the shape of the inner and outer surfaces for the sidewalls is the same, so that sidewalls 120 and 122 have a constant thickness. The sidewall surface shapes are selected to provide the light concentrating effects by directing light entering collector 110 to be directed to absorbing element 150. Here, the sidewall surface shape refers to the curvature of the sidewall surfaces in the x-y plane. In certain embodiments, the sidewall surfaces are parabolic in shape, as shown in FIG. 1B.

Sidewalls 120 and 122 are formed from a material having a first refractive index, N1. In general, as used herein, “refractive index” refers to the refractive index of a material in the portion of the electromagnetic spectrum in which the collector is operational (e.g., in a range spanning the visible spectrum, such as from the near ultraviolet (UV) to the near infrared (IR) region). Where refractive indexes of different media are compared, they should be compared at the same wavelength. Exemplary materials for sidewalls 120 and 122 are discussed below. Generally, N1>1. For example, N1 can be 1.4 or more (e.g., 1.5 or more, 1.6 or more, 1.7 or more, 1.8 or more, 1.9 or more, 2.0 or more).

The hollow body is filled with a fluid (e.g., a liquid, such as water) having a refractive index N2>1. In general, N1 is different from N2. For example, in certain embodiments, N1>N2. In some embodiments, N2 is 1.6 or less (e.g., 1.55 or less, 1.5 or less, 1.45 or less, 1.41 or less, 1.4 or less, 1.35 or less).

Entrance wall 128 has an inner surface 1282, which faces hollow body 120, and an outer surface 1281 opposite inner surface 1282. Entrance wall 128 is a planar element, with inner and outer surfaces 1282 and 1281 being flat, parallel surfaces (parallel to the x-z plane).

Refractive elements 140 and 142 are also planar elements, having parallel flat surfaces. Specifically, refractive element 140 has an inner surface 1401 and an outer surface 1402. Refractive element 142 has an inner surface 1421 forming an interface with outer surface 1402 of refractive element 140. The outer surface of refractive element 142 is exit surface 115 of collector 110.

Entrance wall 128 and exit walls 140 and 142 are formed from materials that are substantially transparent at wavelengths of interest (e.g., from 300 nm to 1,100 nm). Refracting element 140 is formed from a material having a refractive index N4. In some embodiments, N4>N2. Refracting element 142 is formed from a material having a refractive index N5 different from N4 (e.g., greater than N4). In certain embodiments, N5>N4>N2.

Collector 110 acts to concentrate light on absorbing element 150 as follows. For light incident on entrance wall 128 over a range of angles, the light is transmitted into body 130 refracting at outer surface 1281 and again at inner surface 1282. Obviously, light normally incident at surface 1281 is not refracted, but light incident at non-normal angles will be refracted towards the plane 101 due to entrance wall 128 having a refractive index larger that that of its ambient environment, typically air. The line L shows an exemplary incoming light ray. Ray L propagates through the medium filling body 120 and is incident on inner surface 1202 of sidewall 120. Here, a portion of the light is transmitted into sidewall 120, while a portion of it is reflected back into body 120. The transmitted portion is incident on outer surface 1201 where it is reflected, and at least part of it is transmitted back into body 120 where it propagates parallel to the light initially reflected at surface 1202. This path of the light initially reflected at surface 1202 is labeled L1, while the path of the light reflected at surface 1201 is labeled L2. In general, since N1 is typically greater than the refractive index of the ambient atmosphere, total internal reflection can occur at outer surface 1201 and no light propagating along path L exits collector 110 through sidewall 120. Specifically, total internal reflection will occur where the light is incident on surface 1201 at an angle of incidence greater than the critical angle. In some embodiments, where the refractive index of the fluid, N2, is greater than the refractive index N1 of sidewall 120, total internal reflection of light can occur at inner surface 1202 and all light incident on that surface along path L is reflected along path L1.

Referring also to FIG. 1C, light propagating along both L1 and L2 refract at surface 1401 of refracting plate 140. Since N4 is greater than N2, this light refracts towards plane 101. The light is again refracted at the interface between surface 1402 and surface 1421 of refractive element 142. Where N5 is greater than N4, the light again refracts towards plane 101 as it enters refractive element 142. The light exits refractive element 142 through exit surface 115 and impinges on absorber element 150.

Naturally, at least some light that is incident on entrance wall 128 will propagate through body 130 without reflecting from either sidewall. For example, light normally incident on entrance wall 128 in plane 101 will not impinge on either sidewall.

Furthermore, certain light incident on entrance wall 128 at very high angles of incidence will not be collected onto absorber element 150. For example, light incident at very high angles (e.g., 60° or more) will largely be reflected from surface 1281 or, for that light transmitted into body 130, will impinge on a sidewall at a near normal angle of incidence and will be transmitted through the sidewall. Accordingly, there exists a range of incident angles for which incident light will be collected onto absorber element 150. In general, this range depends both on the geometry of the various elements forming collector 110, and on their refractive indexes. The range of angles can be parameterized by an acceptance angle, θₘₐₓ, which corresponds to the highest angle of incidence ray that is concentrated onto the absorber element incident at an edge of the acceptance aperture. In some embodiments, acceptance angle can be 15° or more (e.g., 16° or more, 17° or more, 18° or more, 19° or more, 20° or more, 21° or more, 22° or more, 23.5° or more, 25° or more, 28° or more, such as up to 35° , up to 30°).

In general, the physical size of collector 110 can vary, depending on the size of absorbing element 150 that the collector needs to concentrate light onto. In certain implementations, a relatively small size is desired. For example, in cases where the collector is part of a solar panel system for installation on a rooftop, a relatively small design is desirable to avoid excessive weight associated with larger collectors.

In some embodiments, collector 110 has a height of about 10 cm or less (e.g., about 8 cm or less, about 7 cm or less, about 6 cm or less, about 5 cm or less, about 4 cm or less). Here, the height refers to the dimension of the collector in along the y-axis.

In general, sidewalls 120 and 122, entrance wall 128, and the end wall formed from refractive elements 140 and 142 should be sufficiently thick to provide the mechanical strength required to hold the fluid in hollow body 130. It can be advantageous for these elements to be relatively thin, however, to reduce materials cost and the weight of the collector (especially prior to filling the collector with fluid). In some embodiments, sidewalls 120 and 122 have a thickness in a range from 0.5 mm to about 5 mm (e.g., about 1 mm, about 1.5 mm, about 2 mm, about 2.5 mm, about 3 mm).

The thickness of entrance wall 128 can vary as desired. In some embodiments, entrance wall can have a thickness of about 5 mm or less (e.g., 3 mm or less, 2 mm or less, 1 mm or less, 0.5 mm or less. Since entrance wall 128 is typically not load bearing, it can be thin relative, e.g., to sidewalls 120, 122, and to exit wall 138.

Exit wall 138 should be sufficiently thick to provide sufficient structural support for the other components of collector 110. In embodiments, exit wall 138 has a thickness of about 5 mm or more (e.g., 6 mm or more, 7 mm or more, 8 mm or more, 10 mm or more, 12 mm or more, 15 mm or more, 20 mm or more).

The relative thickness of the refractive elements composing exit wall 138 can also vary. In some embodiment, refractive elements 140 and 142 have equal thickness. Alternatively, the relative thickness of refractive elements 140 and 142 can differ. For example, the thickness of element 140 can be 50% or more (e.g., 75% or more, 125% or more, 150% or more, 200% or more) of the thickness of element 142. In embodiments, element 140 and/or element 142 has a thickness of 1 mm or more (e.g., 2 mm or more, 3 mm or more, 4 mm or more, 5 mm or more, 6 mm or more, 7 mm or more, 8 mm or more, 9 mm or more, 10 mm or more, 11 mm or more, 12 mm or more, 13 mm or more, 14 mm or more, 15 mm or more). The thickness of each element can be selected to increase the collection efficiency of the collector 110.

In general, the thickness of the refractive element(s) depends on the desired acceptance angle of the concentrator and the refractive indices of the liquid and the refractive elements. Economic factors may also be considered when establishing the thickness and refractive index of each refractive element. For example, in general, higher refractive index materials tend to be more expensive that lower refractive index ones, especially for materials having refractive indices greater than about 1.55-1.6. Accordingly, in certain embodiments, the refractive element furthest from the absorber element is the thickest refractive elements and has the lowest refractive index of the refractive elements. Refractive elements can be progressively thinner the closer they are to the absorber.

The width of collector 110 can also vary. Here, the width refers to the dimension of the collector in the x-direction. Generally, the collector has a maximum width at entrance wall 128, corresponding to the entrance aperture. Typically, the maximum width is less than the height of the collector. In some embodiments, collector 110 has a width of 8 cm or less (e.g., 6 cm or less, 5 cm or less, 4 cm or less, 3 cm or less). In general, collector 110 narrows from entrance wall 128 to exit surface 115. The ratio of the widths at entrance wall 128 to exit surface 115 defines the collection power of the collector. For example, an embodiment having a width at entrance wall 128 that is five times the width at exit surface 115 has a collection power of 5 (it is referred to as a 5× collector). In general, the collection power of collector 110 can vary. In some embodiments, collector 110 has a collection power in a range from about 3× to about 10× (e.g., about 4× or more, about 5× or more, about 6× or more, about 7× or more, about 8× or more).

Typically, absorber element 150 is a photovoltaic device, such as a silicon-based solar cell (e.g., mono- or poly-crystalline Si, amorphous Si, thin film Si). Photovoltaics based on other semiconductors can also be used (e.g., Copper indium gallium (di)selenide (CIGS)).). For certain applications, the absorber is a multi junction photovoltaic cell. In some embodiments, absorber element 150 can be an organic photovoltaic device, such as solar cells based on small-molecule or polymeric organic semiconductors. Alternatively, or additionally, the absorber element can be a heat transfer absorbers. In some embodiments, the collector itself can serve as a heat transfer absorber by providing warm water that is used in the collector via a cooling loop, for example.

While collector 110 features sidewalls having constant thickness and parabolic surfaces, in general, other sidewall shapes are also possible. In general, the shape of the sidewalls is selected to provide high light collection efficiency, while being relatively thin (e.g., to keep material costs relatively low) but providing sufficient mechanical strength to withstand the weight of the fluid in the hollow body and the environmental stresses it is likely to encounter in the field (e.g., temperature variations, wind, and precipitation). Sidewall surface shape can be determined, e.g., using computer modeling software to model, and optimize, the performance of prospective shapes.

Generally, the shape of the outer and inner sidewall surfaces are each one of several free parameters that may be simultaneously varied to optimize the performance of a collector. Other free parameters include the refractive index for each portion of the collector, the shape of the entrance surface, and the shape(s) of the refractive element(s) surfaces.

In certain implementations, one can select either the outer surface of the entrance wall or sidewall outer surface shape first, then select the other of that pair, and finally select the shapes of the sidewall inner profile and/or exit refractor(s) to optimize the concentrator for efficiency, compactness, or other desired properties.

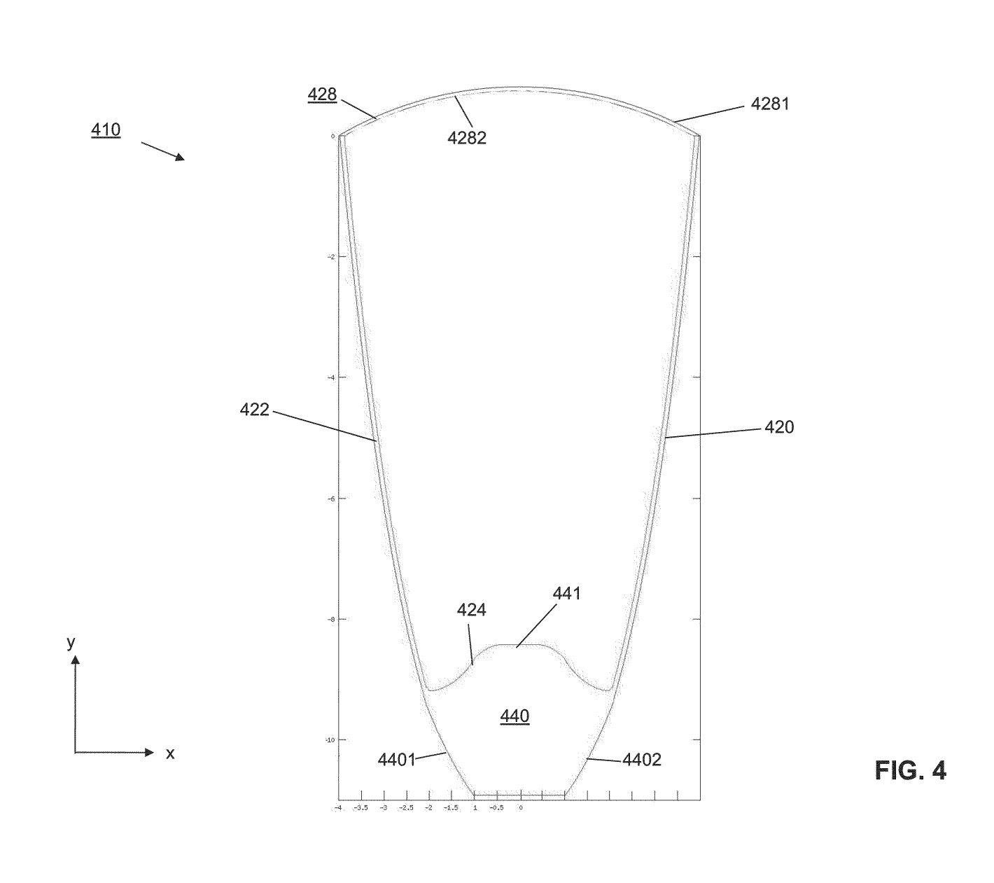

In some embodiments, the outer surface of the entrance wall can be selected to be planar and outer surface of the sidewalls can be parabolic, such as shown in FIG. 1. In certain embodiments, the outer surface of the entrance wall can be convex (e.g., circular, such as spherical or cylindrical) and the outer surface of the sidewalls can be hyperbolic (see FIG. 4, infra). In either case, local departures from the overall sidewall shape may be permitted by varying the geometry of the exit refractor(s) and/or sidewall inner surface shape. Typically, these should be determined numerically, as analytical solutions exist only for some (often trivial) cases.

In some embodiments, collectors can feature sidewall surfaces composed of segments having different shapes. In some embodiments, one segment of a sidewall surface can have a first parabolic shape, while another segment of the same surface has a different parabolic shape or a non-parabolic shape (e.g., a linear shape, a higher order polynomial shape, or a hyperbolic shape). In some embodiments, sidewalls can be composed of surfaces having more than two segment (e.g., three or more segments, four or more segments, five or more segments).

In certain embodiments, the inner and outer sidewall surfaces can have different shapes. For example, the inner and outer sidewall surfaces can have different parabolic shapes. In certain embodiments, at least a segment of the inner sidewall surface can be parabolic, while the adjacent segment of the outer surface is non-parabolic in shape (e.g., a linear shape, a higher order polynomial shape, or a hyperbolic shape). Alternatively, in some embodiments, at least a segment of the outer sidewall surface can be parabolic, while the inner surface is non-parabolic in shape (e.g., a linear shape, a higher order polynomial shape, or a hyperbolic shape).

Furthermore, while sidewalls 120 and 122 have a constant thickness, in some embodiments, collectors can feature sidewalls having varying thickness. For example, a collector can feature sidewalls that have a thickness that increases from its entrance wall to its exit wall. Such sidewalls may provide structural advantages, allowing for relatively thin sidewalls nearer the entrance wall, supported by thicker sidewalls nearer the exit wall. Sidewalls of varying thickness can also provide improved collection efficiency relative to similar collectors having sidewalls of constant thickness.

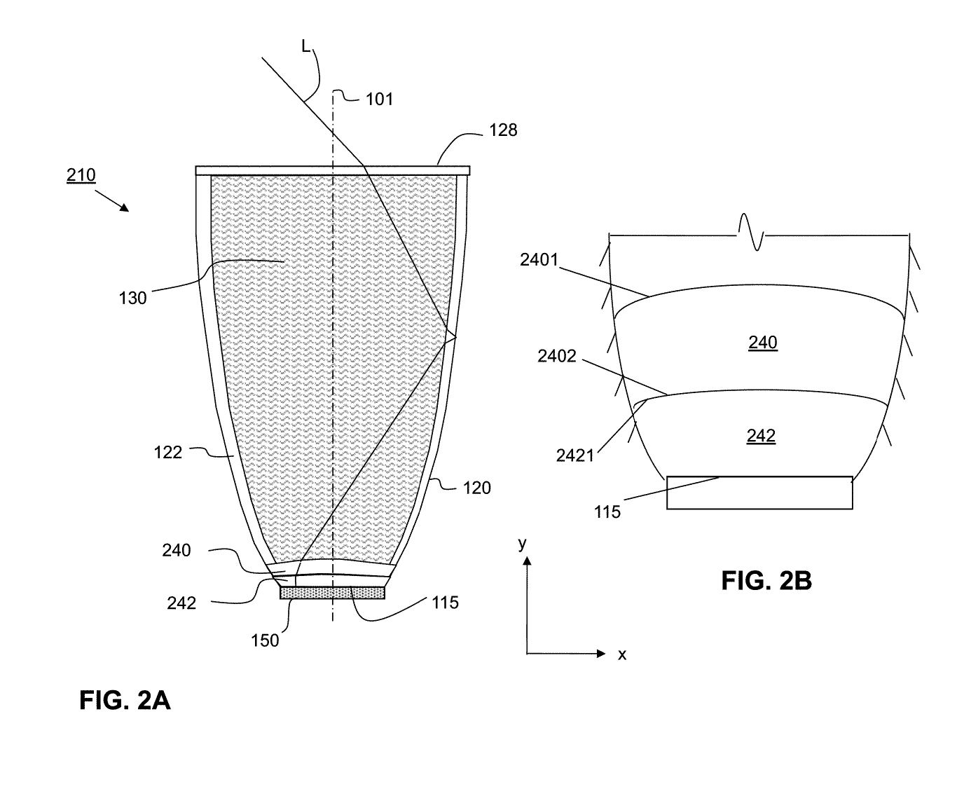

As mentioned previously, the shape of the refractive element(s) can be treated as a free parameter when optimizing the shape of collector components. So, while refractive elements 140 and 142 in collector 110 are planar in shape, having parallel, flat surfaces, in some embodiments, end walls 140 and/or 142 can include one or more non-planar surfaces. For example, referring to FIG. 2A and FIG. 2B, a collector 210 includes refractive elements 240 and 242 that have curved surfaces. Specifically, refractive element 240 includes a convex inner surface 2401 and concave outer surface 2402. Inner surface 2421 of refractive element 242 is convex in shape, conforming to outer surface 2402. Exit surface 115 is planar.

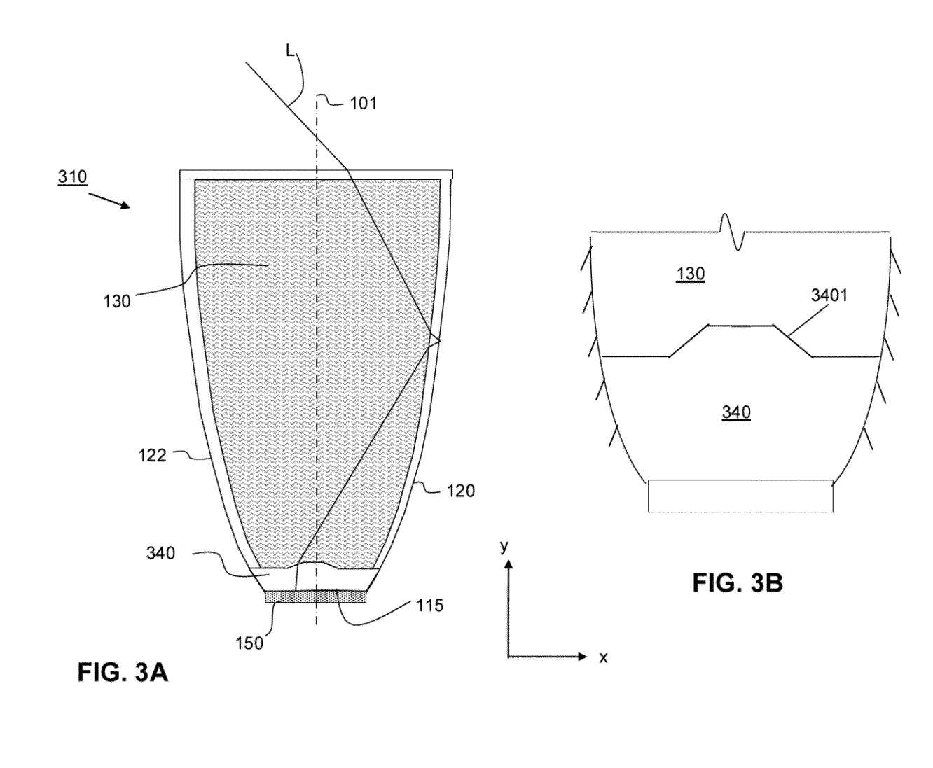

In some embodiments, collectors include a refractive element that has a piece-wise planar surface. For example, referring to FIG. 3A and FIG. 3B, a collector 310 includes a refractive element 340 having an inner surface 3401 composed of several planar portions. These portions are arranged such that surface 3401 is generally planar but has a ridge centered about reference plane 101. As shown, the ridge takes the form of a trapezoid, i.e., having a planar central portion and two sloping planar sides. Light rays passing through these sloping sides are refracted at a different angle than light rays passing through the substantially horizontal planar portions of the refracting element. Such a refracting element may be said to have a piecewise planar upper surface, employing a trapezoidal shaped ridge. Other piecewise planar surfaces are also possible.

This shape of surfaces 3401 and 3421 can serve to further increase the effective collection angle of the concentrator. For example, in function, these convex refracting elements perform a function analogous to cylindrical lenses, focusing incident light towards absorber element 150.

In general, the width of each portion and its angular orientation with respect to the x-axis can vary as desired. As explained below, each of these parameter values can be determined via computer modeling to provide improved concentration efficiency for the collector.

While collector 110 has two refracting elements (140 and 142), more generally, collectors can include exit walls having a single refractive element or more that two refracting elements, each having a refractive index different from the adjacent refracting elements. For example, exit walls can include three or more refractive elements (e.g., four or more, five or more, six or more, seven or more, eight or more refractive elements). In some embodiments, collectors can include three or more adjacent refractive elements having increasing refractive indexes, the refractive element with the highest refractive index being positioned adjacent absorber element 150.

Furthermore, while entrance wall 128 is planar in collectors 110, 210, and 310, having a flat entrance surface 1281 and exit surface 1282, in general, entrance wall 120 can have curved surfaces as well. For example, referring to FIG. 4, a collector 410 has an entrance wall 428 that has a spherical convex entrance surface 4281 and a concave exit surface 4282 parallel to surface 4281. While entrance surface 4281 is spherical, in general, the curvature of the entrance surface can be spherical or aspherical. This curvature can increase the collection angle for collector 410 relative to similar collectors having a flat entrance surface due to, for example, a focusing effect of the entrance wall.

Collector 410 includes sidewalls 420 and 422 both of which have hyperbolic outer surfaces. Selection of their precise shape is discussed more below. Collector 410 also includes an exit wall 440 formed from a single refractive element. The exit wall includes an entrance surface 424 that includes a central ridge 441. Exit wall 440 also feature curved side surfaces 4401 and 4402. Surfaces 4401 and 4402 can have the same shape as the outer surface of the outer surfaces of the sidewalls, or can have different curvatures. For example, the shape of surfaces 4401 and 4402 can be optimized independently of the shape of the sidewalls in order to further enhance the efficiency of collector 410.

While surface 4282 is parallel to surface 4281, in some embodiments this surface can have other curvatures (e.g., planar, convex or concave). For example, the entrance wall can be a double convex lens or a convex-concave lens (e.g., with unequal curvatures). In certain embodiments, the entrance wall can be a Fresnel lens (e.g., a one-sided or two-sided Fresnel lens).

In some embodiments, the inner surfaces of the sidewalls are continuously curved with the entrance surface of the exit wall. For example, referring still to FIG. 4, exit wall surface 424 is a surface that curves continuously from the inner surface of sidewall 422 to exit wall 440 to sidewall 420. Surface 424 includes a ridge 441 at the center of exit wall 440. Ridge 441 has a flat central portion, but curves smoothly to the inner surface of the exit walls.

In such a collector, the sidewalls and exit wall can be formed from a single, continuous piece of material.

In general, a variety of materials can be used for the different components of collector 110. Typically walls 120, 122, 128, and 138 are made of any suitable transparent material, such as a transparent polymeric material or inorganic glass. The materials of construction should be chosen to be compatible with the specific absorber element that receives the concentrated light. Optically, the walls of the hollow body should have a relatively high refractive index, be transparent in the desired part of the spectrum (such as the visible and near infrared part of the spectrum), and be durable. For example, these components can be made from polycarbonate (“PC”) (e.g., UV stabilized PC), although other transparent polymeric materials, such as poly methyl methacrylate (“PMMA”) (e.g., UV stabilized PMMA), may be used. Commercially available materials can be used. For example, both UV stabilized and unstabilized PC are commercially available.

In some embodiments, one or more of the components can be made from an inorganic glass. A number of types of glass, such as crown glass having a typical index ≈1.52 or a flint glass having refractive index ranging between 1.45 and 2.00 may be used. For example, in some embodiments, exit wall 138 can be composed of refractive elements formed from different glasses. As an example, a crown glass (e.g., having refractive index 1.52) may used for the refracting element 140, while a flint glass (e.g., designated SK) (e.g., having refractive index 1.746) is used for refracting element 142.

As well as the specific material named “crown glass” produced from alkali-lime (RCH) silicates that contain approximately 10% potassium oxide, there are other optical glasses with similar properties that are also called crown glasses. Generally, a “crown glass” refers to any glass with Abbe numbers in the range 50 to 85. For example, the borosilicate glass known as Schott BK7 is a common crown glass, used in precision lenses. Borosilicates typically contain about 10% boric oxide, have good optical and mechanical characteristics, and are resistant to chemical and environmental damage. Other additives used in crown glasses include zinc oxide, phosphorus pentoxide, barium oxide, and fluorite.

Flint glasses typically have refractive indices ranging between 1.45 and 2.00. The specific flint glass (designated SK) discussed above has a composition 62% PbO, 33% Sift, 5% K₂O.

Refracting elements can also be formed from materials such as Titania (TiO2). In some embodiments, titania having a crystal morphology called Brookite, which has a refractive index of 2.58, can be used. For example, in embodiments featuring three or more refracting elements, the refracting element closest to absorber element 150 can be formed from Titania.

In certain embodiments, the entrance wall is formed from a material that has low transmission in the UV (e.g., a UV opaque material). For example, many glasses commonly used for visible light are UV opaque. UV opaque or stabilized polymers may also be used. In such cases, the rest of the collector body may not need to be made of UV stable materials. For example, where absorption or reflection of UV light by the entrance wall significantly reduces UV exposure of the other collector components, the requirements for UV stability of those components may be relaxed.

The entire body of the collector may be formed as a single unit, or the collector may be composed of individual components suitably joined together, such as with an adhesive.

The fluid filling hollow body 120 may be any transparent liquid compatible with other materials used to make up the concentrator. Water and aqueous solutions, such as those containing common salt or water-soluble organic liquids are also considered suitable. Glycerin, having an index of 1.47, can also be used. As a specific example, in some embodiments, a collector includes sidewalls and an exit wall composed of PC (having a refractive index of 1.586), while the hollow body is filled with water (having refractive index 1.32). This combination of materials allows a concentrator with an 18.5° acceptance angle and a concentration power of 5× at relatively low cost.

While the above description refers to trough-shaped collectors having a uniform cross-section along the reference axis, other configurations are also possible. For example, collectors that do not have a uniform cross-section can also be used. For example, collectors can have an ellipsoidal or circular shape in the x-z plane.

In general, collectors can be designed in a variety of ways. In some embodiments, collectors can be designed based on the design principles of Compound Parabolic Concentrators (CPC's) set forth in U.S. Pat. No. 4,240,692 to Winston (hereinafter “the '692 patent”), the entire contents of which are incorporated herein by reference. In equation (7) of the '692 patent, an acceptance angle, θₘₐₓ, for a CPC formed of a single optical medium is defined as:

sin θₘₐₓ≧n(1−2/n²),

where n is the relative refractive index of the collector, namely the ratio of the refractive index of the CPC to the refractive index of the ambient medium (e.g., air). This equation will be referred to in the discussion that follows.

For ease of explanation, the concentrators described below are assumed to be oriented with the entrance up and the exit down. The refractive indexes of the materials that will fill the concentrator are simply referred to as Nd_{Low}, Nd_{Mid}, and Nd_{High}, corresponding to a relatively low refractive index material (e.g., N2, the filling fluid refractive index), an intermediate refractive index material (e.g., N1, the sidewall refractive index), and a relatively high refractive index material (e.g., N4 or N5, a refractive element refractive index).

In some embodiments, a two layer collector can be designed as follows. Here, the first layer can be considered as the portion of the collector corresponding to the fluid filled hollow body, while the second layer corresponds to a refractive element in the exit wall, for example. One begins by selecting a parabolic collector profile with an acceptance angle that is permitted by the equation for θₘₐₓ above when considering n=Nd_{High}. By calculation or simulation, it is straightforward to find a point on the side wall where the curvature of the side wall is too steep to allow a material with Nd_{Low} to act as a CPC (i.e., at that point, the curvature of the side is too great to reflect rays entering at the acceptance angle to the opposite focus by total internal reflection (TIR), and so the rays escape the concentrator at that point.) This point establishes the cutoff between the hollow body and the refractive element of the exit wall. Below the point, the collector is filled with the Nd_{High} material (i.e., corresponds to the refractive element); above that point, the Nd_{Low} material will suffice (i.e., the fluid filled hollow body).

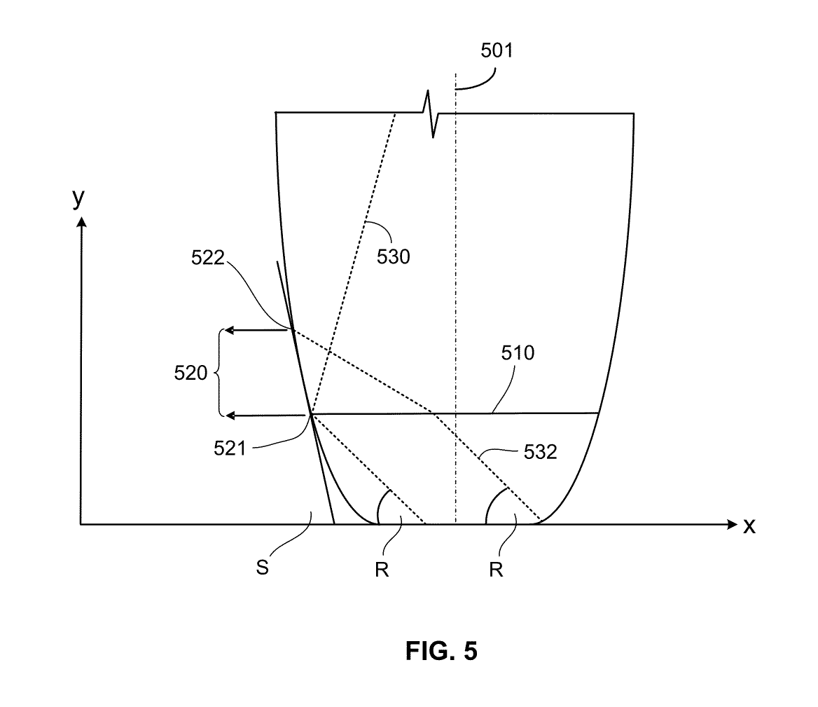

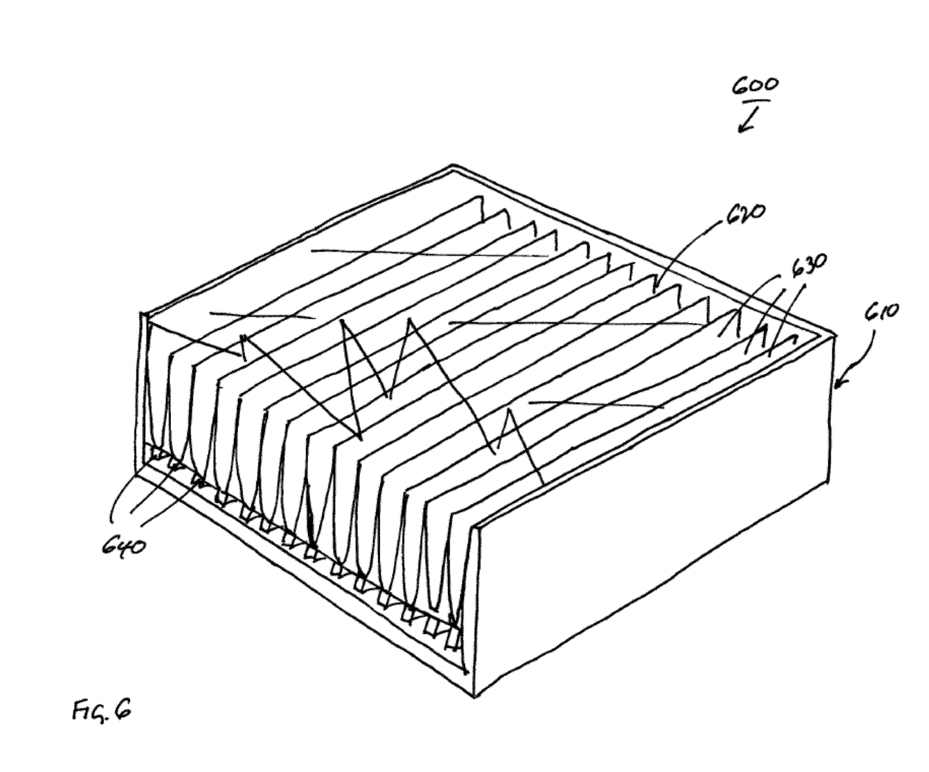

In some embodiments, this design principle can be extended to include a two-layer concentrator with sidewalls surfaces that are part-linear in shape. Specifically, with reference to FIG. 5, a two-layer design can be improved by keeping the parabolic profile below a Nd_{Low}/Nd_{High} boundary 510 (e.g., corresponding to the boundary between the fluid filled hollow body and the exit wall), and calculating a new profile, including a linear section 520, above it. The linear section 520 extends between a point 521 at the location where boundary 520 meets the sidewall, and a point 522 that is established as follows. First, one determines the angle of incidence of a light ray 530 reflected at point 521 on the exit surface. This is labeled R in FIG. 5. Next, one traces a ray 532 from the point where the opposite sidewall meets the exit surface at angle R. Point 522 is the point where ray 532 meets the first sidewall. The orientation of linear section 520 is established from angle S, the angle of the tangent of the sidewall at point 521.

In certain embodiments, additional linear sections can be added as follows. Additional rays are extended and refracted from the opposite focus, allowing the ray angle to vary between -R (that is, parallel to R, but in the opposite direction) and parallel to an axis 501 (which lies in the symmetry plane of the collector). For each of these rays, starting from -R, the wall profile is extended in small linear segments, the segments being at angles to reflect the ray to the acceptance angle. When the wall angle is parallel to the concentrator axis, the adding of segments stops.

In some embodiments, efficiency can be increased further by raising the Nd_{Low}-Nd_{High} boundary towards the entrance wall, maintaining the parabolic profile below the boundary. For example, the sidewall can be extended by a linear section if the boundary is below the 522 found for this new boundary height. Above the linear section (or at the boundary if no linear section was needed) the sidewall can be extended by the small reflecting segment method discussed previously.

The height to which the boundary is to be raised can depend on, for example, a comparison between the value of the additional efficiency gained to the additional cost of the materials, as higher Nd materials are usually more expensive than lower ones. Additional refractive elements can be added, for example, using the following methodology. In principle, a collector having two refractive elements can be considered as a three-layer collector, having three discrete layers with differing refractive index separated by two refractive boundaries. In embodiments, a parabolic boundary can be retained below the first boundary. The angles S and R are calculated as described above. It is noted that S is the steepest angle possible for a sidewall of material with Nd_{Low} to reflect light by total-internal-reflection at a given acceptance angle. Analogous angles S′ and R′ are also calculated, where S′ is the side wall angle for an Nd_{Mid} material (e.g., the upper refractive element), and R′ is the angle of the light reflected from it, when refracted in to Nd_{High}.

A linear section can be added to the sidewall now, however, empirical results may suggest that it is better to use a variation on the small reflecting segment method to extend the sidewall. However, the ray angle starts not at the opposite focus, but at the point where the ray from the boundary point intersects the exit. Additionally, the ray angle varies only from -R′ to -R.

Above this curved section, a linear section can be extended at angle R, its end points being determined by starting a ray from the opposite focus, refracting it through the intervening materials, and finding its intersection with the linear section. Finally, a curved section can be extended from the linear section, using the method described for a two layer collector above, with the addition of the refraction caused by Nd_{Mid}.

The boundaries between the three layers can be adjusted using the same principle described previously for the two-layer system. Here, an additional sidewall can be generated as explained previously for the two-layer system as well. Further, the boundaries can be raised independently of each other, so long as the Nd_{Mid}-Nd_{Low} boundary is kept above the Nd_{High}-Nd_{Mid} boundary. Generally, the specific locations of the boundaries can depend on the efficiency vs. cost trade-offs discussed previously with respect to the two-layer system.

By way of example, in some embodiments, a hyperbolic concentrator, such as collector 410 shown in FIG. 4, can be designed as follows. Such embodiments feature a generally hyperbolic outer sidewall profile, and a inner sidewall profile that is largely parallel to the outer sidewall, but at certain point turns away from the sidewall to form the inner surface of the exit wall. Such can be designed as follows.

First, the materials to make up the concentrator are selected: the entrance surface, sidewalls, exit wall (for each refractive element), and liquid.

Next, the desired design parameters are chosen. For a generally hyperbolic concentrator, these are the acceptance angle, concentration ratio (i.e., the ratio of the entrance aperture dimension to exit aperture dimension), and entrance wall curvature. The width of the sidewalls is chosen as well.

From the design parameters, one calculates the focal point of light focused by the entrance wall and the angles of the ray's going to it from the entrance lens, using, e.g., the method described by Xiachui Ning et al., in “Dielectric totally internal reflecting concentrators,” Applied Optics, Vol. 26, No. 2, 15 Jan. 1987. For simplicity, one can use first quadrant angles, and a concentrator oriented vertically. So, the concentrator is oriented entrance surface up-exit wall down, and extremal light rays are entering at from above right. Since the light is entering from the right, one designs the concentrator's left sidewall and left half of the exit wall entrance surface and then determines the right sidewall/right half of the exit wall by symmetry. The ends of the entrance wall are placed at Cartesian coordinates (+/−concentration ratio, 0). The concentrator will have negative y coordinates and the ends of the exit will be x=+/−1. One calculates the minimum y-coordinate (height) of the concentrator by determining where the positive lens end ray crosses the line x=−1.

Next, the hyperbolic equation for the outer sidewall surface is calculated. This is done numerically by iterating through points (x, y) such that y values are less than or equal to the minimum height and determining an x that is less than or equal to −1 that yields a hyperbola also passing through the negative end of the entrance wall and having foci of the lens focus and the positive concentrator exit (1, y).

The outer sidewall profile can now be generated from the negative lens end to the point at which rays passing through the entry lens into liquid and through the sidewall would escape total internal reflection. The inner sidewall is calculated using its width down the point on the same ray between the end of the calculated outer sidewall and the lens focus.

At this point, the inner sidewall surface should curve away from the outer sidewall surface to refract light to keep it within the concentrator by total internal reflection at the outer sidewall. In addition, it should be noted at this point that the outer sidewall, if continued, would generally not pass through the desired concentrator negative exit but passes to the outside of it (i.e., a positions x<−1). So, not only should the inner sidewall surface turn inward (i.e., towards the concentrator axis), the outer surface (i.e., the outer surface of the exit wall) should as well.

Without wishing to be bound by theory, the hyperbolic sidewall with “sufficiently thin” walls should refract light to the concentrator positive exit, but only where the inner and outer sidewall faces are parallel. Where they divergent, there is the possibility that the ray reflected by the sidewall outer face will not reach the exit, but will instead exit the concentrator by the opposite (right-hand) sidewall above the exit.

To determine the extent of this “light leak”, one can consider two other features of the exit wall entrance surface. For example, assuming that the exit element surface, regardless of its specific shape, is continuously differentiable and concave up. The first feature is the point on the exit wall entrance surface that is tangent to a ray from the concentrator positive exit (which is also a focus of the hyperbola that generates the outer sidewall profile). Rays that pass thru the inner sidewall and reflect from the outer sidewall above this point (the “tangent point”) will intersect the exit element surface and will be refracted or reflected to a point on the exit.

The second feature is the point (the “orthogonal point”) at which ray from lens focus is orthogonal to the exit element surface. Rays at the orthogonal point and below should be sufficiently refracted by the exit wall entrance surface so that when they are reflected from the hyperbolic outer sidewall, they will reach the exit.

Thus the extent of the “light leak” is determined by the difference in projections of two rays on the hyperbolic outer sidewall: one is the projection of the ray from through the tangent point, and the other is projection of the ray from the lens focus to the orthogonal point. Between these projected points, light arriving at the concentrator at angles close to the concentrator's design acceptance angle should “leak” from the concentrator (i.e., not pass through the exit aperture). As the arrival angle of the light falls from the acceptance angle, the size of the leak should diminish and eventually disappear.

There are a number of ways to minimize the size of the light leak. For example, one way is to treat the sidewall material as though it had a lower refractive index than it does, and simply calculate the angle of the exit wall surface to refract light rays passing through it such that the sidewall will be able to totally internally reflect them at its lower effective refractive index. To avoid a cusp where the inner sidewall turns away from being parallel to the outer sidewall, the lowering of the refractive index can be done smoothly. This method is of finding the exit element surface is the “low effective refractive index method”. Appropriate values of the lower refractive index and factor to smoothly lower it to minimize the size of the light leak can be readily determined empirically.

For collector 410 shown in FIG. 4 designed in this way, the light leak can affect about 5.5% of the sidewall at its maximum extent, yielding a concentrator 94.5% ideal. Further improvements in efficiency may be possible, for example, using an aspherical entrance wall outer surface.

The exit wall entrance surface and outer surfaces can be extended iteratively to reach the orthogonal point and its projection as described above.

From the orthogonal projection point on the outer sidewall surface, the outer surface can now be deflected inward so that it reaches the concentrator negative exit. There are a number of ways to do this as well. For example, one may notice that while the light ray passing through the orthogonal point and its projection point is reflected by the sidewall to the positive concentrator exit point, if both these surfaces were to be extended using their existing methods—that is, extending the outer surface on the existing hyperbola and continuing the exit element surface by the low effective refractive index method, rays entering the concentrator at its acceptance angle so they'd pass to the right/below these points will be refracted by the exit element surface and reflected by the sidewall will pass through the exit with smaller x coordinates. Which is to say, the curvature of the outer surface could be adjusted to make them pass through the positive concentrator exit point, and this would make the outer surface pass closer to the negative concentrator exit point.

In some embodiments, simply taking advantage of the low effective refractive index method and deflecting the outer surface inward so that its real, higher critical total internal reflection angle is made with the light rays refracted by the exit wall surface provides sufficient deflection to cause it to pass very close to the negative concentrator exit point. If not, slowly lowering the effective refractive index and recalculating the exit wall entrance surface shape and outer surface shape can rapidly find a suitable value. Having done this, the outer surface profile is complete. The exit wall entrance surface can be extended to the point that the ray passing through it from the positive lens corner at the acceptance angle is refracted to the end of the sidewall profile at the negative concentrator exit point.

While the foregoing embodiments are all symmetric about a plane (e.g., having an acceptance angle that is symmetric with respect to an axis of the concentrator), other configurations are also possible. For example, in some embodiments, collectors having an asymmetric acceptance angle can be used. For example, asymmetry can be introduced into the entrance wall, sidewalls, and/or refractive elements that result in a change in the acceptance angle from one side of the collector to the other.

Such collectors may be useful in certain applications. For example, most commercial buildings have flat roofs, but for full-year sunlight acceptance, one should point the concentrators on the roof at the sun's mean yearly angle. This often means mounting the 1 concentrators (e.g., that have a symmetric acceptance angle) on a tilted frame. However, in some embodiments, one could use a collector having an asymmetric acceptance angle and mount them vertically.

Solar collector systems, such as those described above, can be used in a variety of applications, and are typically grouped together to provide light collection to an array of absorber elements arranged on a panel. Referring to FIG. 6, for example, multiple solar collector systems can be arranged in a solar panel module 600. Here, module 600 includes a housing 610 in which multiple collectors 630 are arranged together. Each collector 630 focuses incident radiation onto a corresponding absorber element 640 (e.g., a corresponding photovoltaic element). Module 600 includes a transparent cover 620, which provides the entrance walls for each of the collectors.

In some embodiments, solar collector systems include a coolant loop for managing the system temperature. Such embodiments can include a pump connected to the loop, along with a device to reject heat (e.g., a radiator or a heat exchanger). In certain embodiments, the heat management apparatus can be used to provide domestic hot water. For example, the apparatus can include a heat exchanger that provides hot water. In some embodiments, the liquid (e.g., water) used in the collector can serve also as coolant for the system. Accordingly, the coolant loop can include feeds into and out of the hollow bodies of the collectors. It is noted that as a coolant, water can provide certain advantages: For example, its practically opaque in the IR below (and actually slightly above) the bandgap for Si solar cells, which means significant incident heat ends up in the water, rather than the solar cells. Second, it has a relatively large specific heat, so relatively small volumes can be used to store or reject a lot of heat.

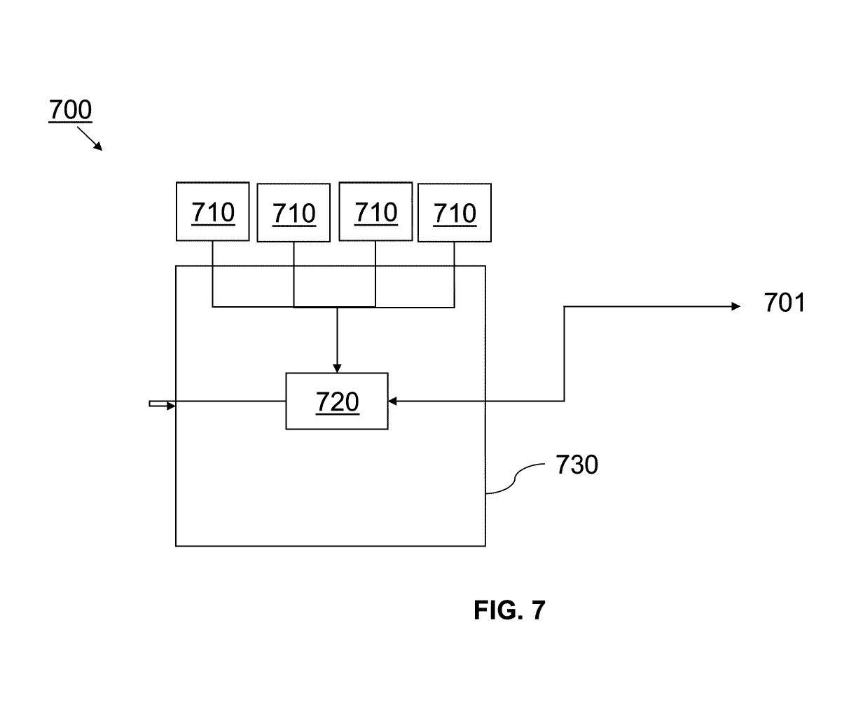

Modules including solar collector systems, such as those described above, can be deployed in a variety of different situations. For example, modules can be mounted on residential dwellings (e.g., single family or multi-family dwellings), commercial buildings (e.g., shopping malls or office buildings) or industrial buildings (e.g., factories). Commonly, modules are used to supply electricity to the building on which they're mounted. For example, referring to FIG. 7, a solar module system 700 is composed of multiple modules 710 mounted on a building 730, connected via regulator 720 to building's utility supply. In some embodiments, the modules can also be used to supply power to the utility grid 701 in addition to building 730. For example, at times when demand from the building 730 is relatively low, regulator 720 can direct excess electricity to grid 701. Conversely, when demand from building 730 excess the generation capacity of system 700, supplemental electricity can be supplied from grid 701.

Collectors having high acceptance angles, such as those described above, can be used in modules without tracking systems to provide electricity year round (or almost year round, such as for 9-10 months of the year), e.g., even when installed at sub-tropical or temperate locations.

Other embodiments are within the scope of the following claims.

What is claimed is:

1. An apparatus, comprising:
a light concentrator which during operation directs light from an entrance aperture and an exit aperture; and
a photovoltaic device positioned relative to the exit aperture to receive the light, wherein the light concentrator comprises a hollow body formed from a pair of spaced-apart sidewalls and an exit wall connecting the sidewalls,
each sidewall being formed from a material having a first refractive index, n₁,
the exit wall comprises a first element having an exit surface positioned at the exit aperture, the first element being formed from a material having second refractive index, n₂, and
the hollow body contains a liquid having a having a refractive index n₃, where n₃<n₁ and n₃<n₂.
